(19) United States
(12) Patent Application Publication
(10) Pub. No.: US 2026/0093398 A1
(43) Pub. Date: Apr. 2, 2026

(54) INTERFACE CONTROL DEVICE AND OPERATING METHOD THEREOF, AND MEMORY DEVICE AND DATA PROCESSING SYSTEM HAVING THE SAME

(71) Applicant: SK hynix Inc., Gyeonggi-do (KR)

(72) Inventors: Bora KIM, Gyeonggi-do (KR); Myeong Jae KIM, Gyeonggi-do (KR); Jihwan KIM, Gyeonggi-do (KR); Chan Hee LEE, Gyeonggi-do (KR); Min Soo LIM, Gyeonggi-do (KR)

(21) Appl. No.: 19/058,008

(22) Filed: Feb. 20, 2025

(30) Foreign Application Priority Data
Sep. 30, 2024 (KR) 10-2024-0132813

(51) Int. Cl. G06F 3/06

(52) U.S. Cl. CPC G06F 3/061; G06F 3/0655; G06F 3/0679

(57) ABSTRACT

An interface control device includes a clock domain crossing (CDC) circuit configured to receive a first signal synchronized with a first clock, and output a second signal corresponding to the first signal synchronized with a second clock, a demultiplexer configured to divide the second signal into a plurality of signals to generate configuration information, a configuration register configured to store the configuration information, and an interface controller configured to operate according to the configuration information stored in the configuration register.

### CROSS-REFERENCES TO RELATED APPLICATION

The present application claims priority under 35 U.S.C. § 119(a) to Korean Patent Application Number 10-2024-0132813, filed on Sep. 30, 2024, which is incorporated herein by reference in its entirety.

### BACKGROUND

### 1. Technical Field

Various embodiments of the present disclosure may generally relate to a semiconductor device, and more particularly, to an interface control device and an operating method thereof, and a memory device and a data processing system having the same.

### 2. Related Art

Various nodes constituting a computing system, for example, a processor, an input/output (I/O) device, a memory device, and the like may be electrically coupled to each other through buses.

The nodes within the computing system may use clock frequencies or clock sources different from each other. Clock synchronization may be required to exchange data between the nodes in different clock domains.

Clock domain crossing (CDC) means securely transmitting data by preventing signal distortion according to a difference between clocks in a transmission side and a reception side during transmitting a signal between clock domains which operate with different clocks from each other.

As the computing system becomes larger, a signal exchanged between the nodes may also be increased, and thus a structure of a CDC circuit may also be complicated.

### SUMMARY

Embodiments of the present disclosure are provided to an interface control device capable of miniaturizing a clock domain crossing (CDC) circuit and an operating method thereof, and a memory controller and a data processing system having the same.

In an embodiment of the present disclosure, an interface control device may include a clock domain crossing (CDC) circuit configured to receive, from an external device, a first signal synchronized with a first clock, and output a second signal corresponding to the first signal synchronized with a second clock; a demultiplexer configured to divide the second signal into a plurality of signals to generate configuration information corresponding to the plurality of signals; a configuration register configured to store the configuration information; and an interface controller configured to operate according to the configuration information stored in the configuration register.

In an embodiment of the present disclosure, an operating method of an interface control device may include receiving, from an external device, a first signal synchronized with a first clock; outputting a second signal corresponding to the first signal synchronized with the second clock; dividing the second signal into a plurality of signals to generate configuration information corresponding to the plurality of signals; storing the configuration information; and performing an interfacing operation based on the configuration information.

In an embodiment of the present disclosure, a memory device may include an interface control device; a device group including at least one memory; and a device controller configured to control the device module based on signals provided from an external device through the interface control device. The interface control device may include a clock domain crossing (CDC) circuit configured to receive, from the external device, a first signal synchronized with a first clock, and output a second signal synchronized with a second clock; a demultiplexer configured to divide the second signal into a plurality of signals to generate configuration information corresponding to the plurality of signals; a configuration register configured to store the configuration information; and an interface controller configured to operate according to the configuration information stored in the configuration register.

In an embodiment of the present disclosure, a data processing system may include at least one first device configured to operate in a first clock domain based on a first clock; and at least one second device including an interface control device configured to receive, from the at least one first device, a first signal synchronized with the first clock, and operate in a second clock domain based on a second clock. The interface control device may include a clock domain crossing (CDC) circuit configured to receive, from the first device, the first signal synchronized with the first clock, and output a second signal corresponding to the first signal synchronized with a second clock; a demultiplexer configured to divide the second signal into a plurality of signals to generate configuration information corresponding to the plurality of signals; a configuration register configured to store the configuration information; and an interface controller configured to operate according to the configuration information stored in the configuration register.

According to embodiments of the present disclosure, clock domain crossing (CDC) may be performed in an input terminal edge of computing nodes in clock domains different from each other, and thus the number of logics in a CDC circuit may be reduced. Accordingly, an occupied area and power consumption of the CDC circuit may also be reduced and the performance of the system may be improved.

These and other features, aspects, and embodiments are described in more detail below.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a diagram illustrating a configuration of an interface control device according to an embodiment of the present disclosure;

FIG. 2 is a conceptual diagram illustrating a clock domain crossing (CDC) circuit according to an embodiment of the present disclosure;

FIG. 3 is a conceptual diagram describing an operation of an interface control device according to an embodiment of the present disclosure;

FIG. 4 is a conceptual diagram describing an operation of an interface control device according to an embodiment of the present disclosure;

FIG. 5 is a flowchart describing an operating method of an interface control device according to an embodiment of the present disclosure;

FIG. 6 is a diagram illustrating a configuration of a memory device according to an embodiment of the present disclosure;

FIG. 7 is a diagram illustrating a configuration of a data processing system according to an embodiment of the present disclosure;

FIG. 8 is a diagram illustrating a configuration of a data processing system according to an embodiment of the present disclosure; and

FIG. 9 is a diagram illustrating a configuration of a data processing system according to an embodiment of the present disclosure.

### DETAILED DESCRIPTION

Various embodiments of the present disclosure are described in detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The embodiments of the present disclosure are described herein with reference to cross-section and/or plan illustrations of the embodiments. However, embodiments of the present disclosure should not be construed as limiting the scope of the present disclosure. Although a few embodiments of the present disclosure are shown and described, it will be appreciated by those of ordinary skill in the art that changes may be made in these embodiments without departing from the principles and scope of the present disclosure.

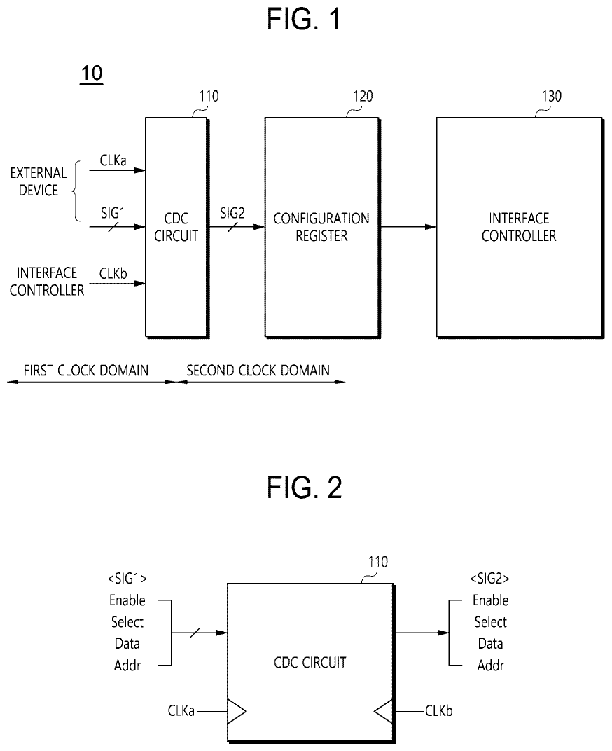

FIG. 1 is a diagram illustrating a configuration of an interface control device 10 according to an embodiment of the present disclosure.

Referring to FIG. 1, the interface control device 10 includes a clock domain crossing (CDC) circuit 110, a configuration register 120, and an interface controller 130.

In an embodiment, the interface control device 10 may be a compute express link (CXL) controller which relays communication between an external device and the interface controller 130 according to a CXL-based protocol.

The interface control device 10 as the CXL controller may perform clock domain crossing on a signal provided from the external device in an application layer, generate configuration information, and store the configuration information in the configuration register 120.

For example, the CDC circuit 110 may receive a first clock CLKa from the external device which operates in a first clock domain and receive a second clock CLKb from the interface controller 130 which operates in a second clock domain.

The external device may refer to a host device. The external device may include at least one among a programmable component such as a central processing unit (CPU), a graphic processing unit (GPU), and a neural processing unit (NPU), a component which provides a fixed function such as an intellectual property (IP) core, a reconfigurable component such as a field programmable gate array (FPGA), and a peripheral apparatus such as a network interface card (NIC).

The external device may transmit a first number of first signals SIG1 to the interface control device 10, for example, a slave device built with the interface control device 10, in synchronization with the first clock CLKa.

The first signal SIG1 may be the configuration information for setting the configuration register 120.

For example, the configuration information may include an operation mode (for example, a memory mode and an input and output (IO) mode) of the slave device, speed and a bandwidth of the slave device, address mapping and a bus setting value between the external device and the slave device, power management information for the slave device, resource allocation information used by the slave device, and the like.

The external device may transmit the first number of first signal SIG1 including data Data indicating details of the configuration information and an address Addr of the configuration register which is to store the data Data to the interface control device 10 in synchronization with the first clock CLKa.

The CDC circuit 110 may output the first number of first signals SIG1 as a second signal SIG2 in synchronization with the second signal CLKb.

The configuration register 120 may store the second signal SIG2.

The interface controller 130 may operate based on the configuration information according to the second signal SIG2 stored in the configuration register 120.

In an input terminal or an output terminal of the CDC circuit, the first number of first signals SIG1 may be divided into a second number of second signals SIG2 according to a bit number of the address Addr through a demultiplexer (not shown) before being stored in the configuration register 120. The number of second signals SIG2 may be increased to the second number (the first number*a demultiplexing rate).

The interface control device 10 may receive the first number of first signals SIG1 in synchronization with the first clock CLKa, demultiplex (divide) the first signals to generate the second number of second signals SIG2, perform CDC-processing on the second signals SIG2, and store the CDC-processed second signals SIG2 in the configuration register 120. In this case, there is a need for a circuit for CDC-processing the second number of second signals SIG2.

In an embodiment, the first number of first signals SIG1 may be CDC-processed in an input edge of the interface control device 10 and then demultiplexed (divided) into the second number of second signals GIG2, and the second number of second signals GIG2 may be stored in the configuration register 120.

The CDC processing may be performed only on the first number of first signals SIG1, and thus the number of circuits for CDC-processing may be reduced as compared with a case where the CDC processing is performed on the second number of second signals SIG2.

FIG. 2 is a conceptual diagram illustrating a CDC circuit 110 according to an embodiment of the present disclosure.

Referring to FIG. 2, the external device may transmit the first signal SIG1 including an enable signal Enable, a select signal Select, data Data as details of the configuration information, and the address Addr of the configuration register which is to store the data Data to the interface control device 10 in synchronization with the first clock CLKa.

The CDC circuit 110 may receive the first clock CLKa, the second clock CLKb, and the first signal SIG1 synchronized with the first clock CLKa. The CDC circuit 110 may output the first signal SIG1 as the second signal SIG2 in synchronization with the second clock CLKb.

The signal which is processed through the CDC circuit 110 may be the first number of first signals SIG1 transmitted from the external device, and the second signals SIG2 which is generated in synchronization with the second clock CLKb may be divided into the second number of second signals SIG2 according to the address Addr before being stored in the configuration register.

For example, the first signal SIG1 may be CDC-processed as the second signal SIG2 and then demultiplexed, and thus the burden on the number of signals to be processed through the CDC circuit 110 may be reduced.

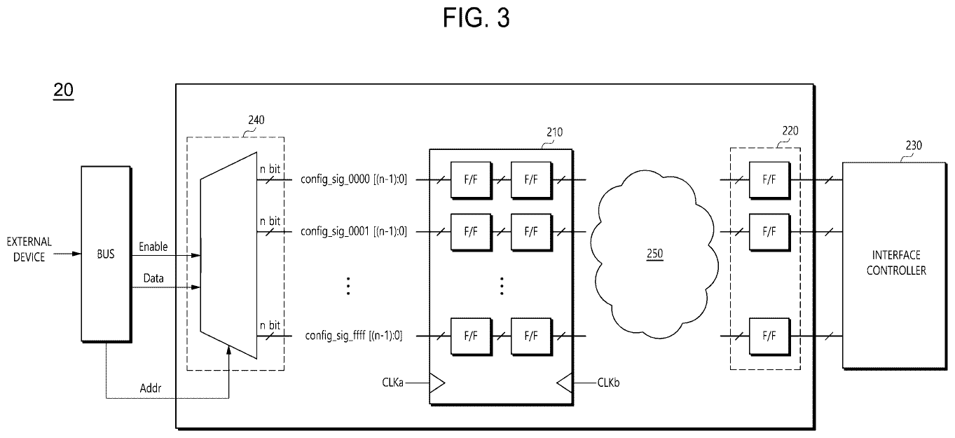

FIG. 3 is a conceptual diagram describing an operation of an interface control device 20 according to an embodiment of the present disclosure.

Referring to FIG. 3, the interface control device 20 may include a demultiplexer 240, a CDC circuit 210, a configuration register 220, and an interface controller 230.

The first signal SIG1, for example, the first number of first signals Enable, Data, and Addr provided from the external device may be transmitted to the interface control device 20 through a bus in synchronization with the first clock CLKa.

The demultiplexer 240 may receive the first number of first signals Enable, Data, and Addr and divide the data Data according to the address Addr to generate a second number of configuration information config_sig_0000[(n-1):0], config_sig_0001[(n-1):0], . . . , config_sig_ffff[(n-1):0].

The CDC circuit 210 may receive the second number of configuration information config_sig_0000[(n-1):0], config_sig_0001[(n-1):0], . . . , config_sig_ffff[(n-1):0] synchronized with the first clock CLKa and output the second number of configuration information as the second signal synchronized with the second clock CLKb.

The second signal output from the CDC circuit 210 may be stored in the configuration register 220 through an internal path 250.

The interface controller 230 may operate based on the configuration information stored in the configuration register 220.

The interface control device 20 in FIG. 3 may divide the first number of first signals into the second number of signals and then perform CDC-processing on the second number of signals. Accordingly, the CDC-processing for the second number of signals, which is increased as compared with the number of first signals transmitted from the external device, has to be performed.

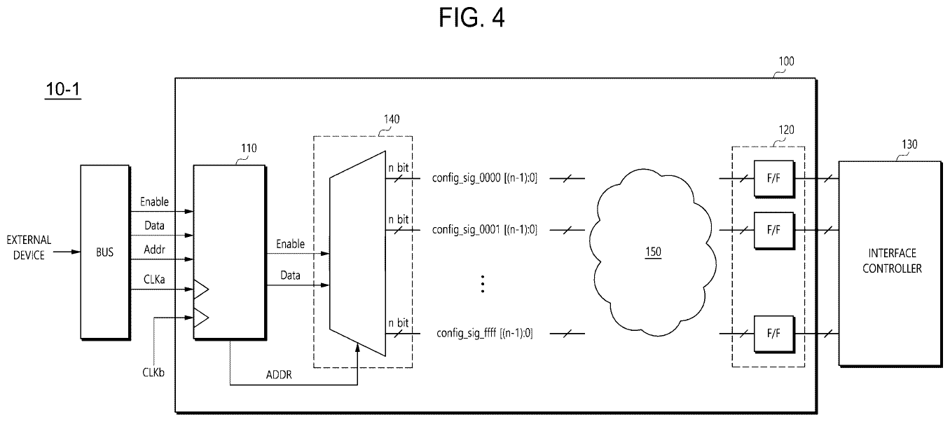

FIG. 4 is a conceptual diagram describing an operation of an interface control device 10-1 according to an embodiment of the present disclosure.

Referring to FIG. 4, the interface control device 10-1 may include an application layer logic 100 and an interface controller 130.

The application layer logic 100 may relay communication between the external device and the interface controller 130 according to a preset protocol, for example, a compute express link (CXL)-based protocol. In an embodiment, the application layer logic 100 may include a CDC circuit 110, a demultiplexer 140, and a configuration register 120.

The first number of first signals Enable, Data, and Addr of the external device may be transmitted to the interface control device 10-1 in synchronization with the first clock CLKa through a bus.

The CDC circuit 110 may output the second signals Enable, Data, and Addr synchronized with the second clock CLKb.

The demultiplexer 140 may receive the second signals Enable, Data, and Addr, and divide the data Data according to the address Addr to generate the second number of configuration information config_sig_0000[(n-1):0], config_sig_0001[(n-1):0], . . . , config_sig_ffff[(n-1):0].

The configuration information config_sig_0000[(n-1):0], config_sig_0001[(n-1):0], . . . , config_sig_ffff[(n-1):0] may be stored in the configuration register 120 through an internal path 150.

The interface controller 130 may operate based on the configuration information stored in the configuration register 120.

The interface control device 10-1 in FIG. 4 may perform CDC-processing on the first number of first signals and then divide the CDC-processed first signals into the second number of signals. Accordingly, the CDC-processing may be performed only on the first number of first signals transmitted from the external device, and thus the CDC circuit 110 may be light-weighted as compared with the interface control device 20 illustrated in FIG. 3. According to the lightweight of the CDC circuit 110, the occupied area and power consumption of the CDC circuit may also be reduced.

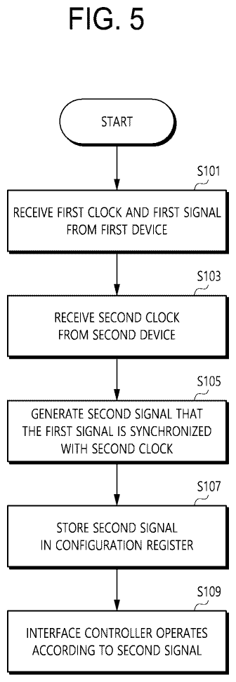

FIG. 5 is a flowchart describing an operating method of an interface control device according to an embodiment of the present disclosure.

Referring to FIG. 5, the interface control device 10 or 10-1 may receive a first clock and a first number of first signals synchronized with the first clock from a first device, for example, an external device (at operation S101).

The interface control device 10 or 10-1 may receive a second clock from a second device, for example, the interface controller 130 (at operation S103).

The interface control device 10 or 10-1 may generate a second signal corresponding to the first signal synchronized with the second clock (at operation S105). In an embodiment, in the operation S105, the interface control device 10 or 10-1 may demultiplex the first signals to be divided into the second number of signals, and generate the second number of signals as the second signal synchronized with the second clock. The second signal synchronized with the second clock may be the second number of configuration information.

The second signal may be stored in the configuration register 120 (at operation S107).

The interface controller 130 may operate based on the second signal stored in the configuration register 120 (at operation S109).

The second number of second signals as the configuration information stored in the configuration register 120 may include an operation mode, operation speed, a bandwidth, address mapping information, a bus setting value, power management information, resource allocation information, and the like.

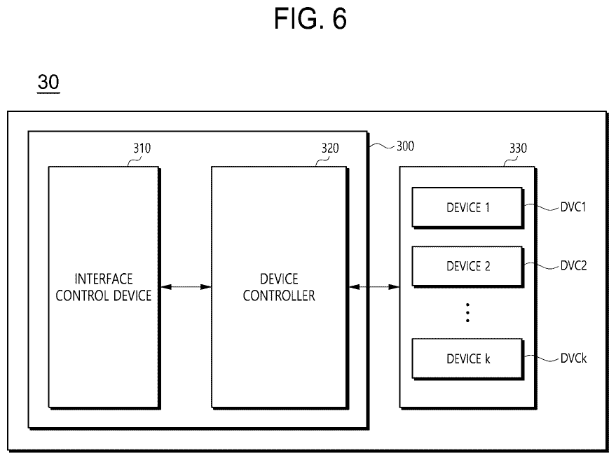

FIG. 6 is a diagram illustrating a configuration of a memory device 30 according to an embodiment of the present disclosure.

Referring to FIG. 6, the memory device 30 may include a memory controller 300 and a device group 330.

The memory controller 300 may include an interface control device 310 and a device controller 320.

For example, the interface control device 310 may be the interface control device 10 illustrated in FIG. 1 or the interface control device 10-1 illustrated in FIG. 4. The interface control device 310 may receive the first clock from the external device which operates in the first clock domain, and receive a second clock from the interface controller, which operates in the second clock domain, in the inside of the interface control device 310. The interface control device 310 may store the second signal generated by synchronizing the first signal, which is transmitted from the external device in synchronization with the first clock, with the second clock in the configuration register of the inside of the interface control device 310. The interface controller may operate according to the second signal of the second domain which is stored in the configuration register.

The device controller 320 may control the device group 330 according to a signal provided from the external device through the interface control device 310.

The device group 330 may include at least one device DVC1, DVC2, . . . , DVCk. The at least one device among the devices DVC1 to DVCk may be a memory device. The memory device may include at least one of nonvolatile memories such as a solid state drive (SSD), a flash memory, a magnetic random access memory (MRAM), a ferroelectric RAM (FRAM), a phase change RAM (PRAM), and a resistive RAM (RRAM) and/or at least one of dynamic random access memories (DRAMs) such as a double data rate synchronous dynamic random access memory (DDR SDRAM), a low power double data rate (LPDDR) SDRAM, a graphics double data rate (GDDR) SDRAM, and a Rambus dynamic random access memory (RDRAM).

In an embodiment, the memory device 30 in FIG. 6 may be a memory device supporting the CXL protocol. In the embodiment, the memory controller 300 may be a CXL controller in which the interface control device 310 and the device controller 320 are mounted on one chip. At least one among the devices DVC1 to DVCk controlled by the CXL controller may be a DRAM.

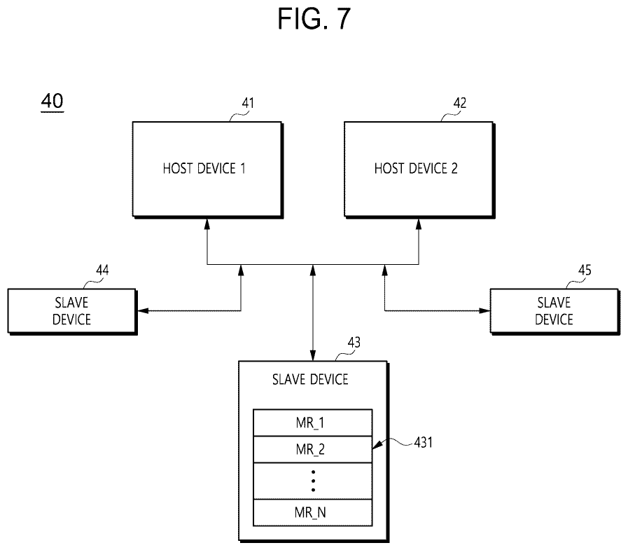

FIG. 7 is a diagram illustrating a configuration of a data processing system 40 according to an embodiment of the present disclosure.

Referring to FIG. 7, the data processing system 40 may include at least one host device 41 and 42 and at least one slave device 43, 44, and 45. Each of the host devices 41 and 42 may request a data access to the at least one slave device 43, 44, and 45. In an embodiment, the slave devices 43, 44, and 45 may include memory devices 431, respectively.

Each of the slave devices 43, 44, and 45 may include various types of memories. For example, the memory device may include at least one of nonvolatile memories such as a solid state drive (SSD), a flash memory, a magnetic random access memory (MRAM), a ferroelectric RAM (FRAM), a phase change RAM (PRAM), and a resistive RAM (RRAM) and/or at least one of dynamic random access memories (DRAMs) such as a double data rate synchronous dynamic random access memory (DDR SDRAM), a low power double data rate (LPDDR) SDRAM, a graphics double data rate (GDDR) SDRAM, and a Rambus dynamic random access memory (RDRAM).

A memory device 431 included in each of the slave devices 43, 44, and 45 may include a plurality of memory regions MR_1, MR_2, . . . , MR_N which are logically and/or physically divided.

The memory regions MR_1 to MR_N may correspond to logically divided logical regions. The memory regions MR_1 to MR_N included in the first slave device 43 as physically divided regions may be recognized as a plurality of devices and independently accessed by the host devices 41 and 42 different from each other in the data processing system 40.

The host devices 41 and 42 and the slave devices 43 to 45 in the data processing system 40 may communicate with each other through an interconnect (or a link) supporting one or more protocols. Each of the devices 41 to 45 may include internal components configured to perform communication based on a protocol supported in the interconnect. For example, the interconnect may support at least one protocol selected from protocols such as peripheral component interconnect express (PCIe), compute express link (CXL), XBus, NVLink, infinity fabric, cache coherent interconnect for accelerators (CCIX), and coherent accelerator processor interface (CAPI).

Although the interconnects between the devices 41 to 45 are briefly illustrated in FIG. 7, the devices 41 to 45 may communicate with each other through root complex (not shown). The root complex may manage the transaction between the devices 41 to 45.

Hereinafter, embodiments of the present disclosure will be described centered on CXL protocol-based communication, but the embodiments of the present disclosure are not limited thereto and various protocols may be applied other than the above-described protocols. For example, the devices 41 to 45 may communicate with each other based on various configurations and functions according to the CXL standard. As an example, the devices 41 to 45 may communicate with each other through various protocols based on the configurations such as a flex bus and a switch disclosed in the CXL standard.

Although not shown in FIG. 7, at least a portion of first to third slaves 43 to 45 may be coupled to a first host device 41 and/or a second host device 42 through a preset protocol-based bridge which controls a communication path.

Each of the first host device 41 and the second host device 42 may include various types of devices. For example, each of the first host device 41 and the second host device 42 may include at least one among a programmable component such as a central processing unit (CPU) which overall controls the data processing system 40 as a main processor, a graphic processing unit (GPU), and a neural processing unit (NPU), a component which provides a fixed function such as an intellectual property (IP) core, a reconfigurable component such as a field programmable gate array (FPGA), and a peripheral apparatus such as a network interface card (NIC).

The slave devices 43 to 45 may be an accelerator which receives and processes the requests of the host devices 41 and 42, such as a graphic processing unit (GPU), a neural processing unit (NPU), and a field programmable gate array (FPGA). In an embodiment, the host devices 41 and 42 may offload operations with a high memory access to the slave devices 43 to 45, and the slave devices 43 to 45 may be referred to as a near data processor (NDP) which stores data required for operations in the memory device 431 and performs the operations on the data, according to the requests of the host devices 41 and 42, and stores the operation results in the memory devices 431.

In an embodiment, at least one of the first to third slave devices 43 to 45 may be shared by the first host device 41 and the second host device 42. For example, when the first slave device 43 is shared by the first host device 41 and the second host device 42, the first slave device 43 may store an instruction which is executed by each of the first host device 41 and the second host device 42 or store data which is inputted for operation processing and/or an operation processing result, and transmit the operation processing result to the first host device 41 and the second host device 42, respectively.

The first and second host devices 41 and 42 and the first to third slave devices 43 to 45 may generate and transmit packets according to adopted protocols, respectively. For example, the first or second host device 41 or 42 may execute hierarchical software including applications to generate a host packet, select the slave devices 43 to 45 to access, and transmit the host packet to the selected slave devices. The host packet generated in the first or second host device 41 or 42 may include an instruction and an access-requested address, and may further include data to be written in the memory devices of the selected slave devices 43 to 45.

The slave devices 43 to 45 which receive the host packet from the first or second host 41 or 42 may parse the host packet to extract the instruction, process the extracted instruction, generate a slave packet corresponding to an instruction processing result, and transmit the slave packet to the first or second host device 41 or 42 which transmits the host packet thereto. The slave packet may include a response for the instruction, data read from the memory devices of the slave devices 43 to 45, and the like.

The slave devices 43 to 45 may include the interface control device 10 illustrated in FIG. 1 to exchange various signals including the host packet and the slave packet with the host devices 41 and 42. The interface control device 10 may receive the first clock from the host devices 41 and 42 which operate in the first clock domain and receive the second clock from the interface controllers in the slave devices 43 to 45 which operate in the second clock domain. The interface control device 10 may synchronize the first signal, for example, the host packet, which is transmitted from the host device 41 and 42 in synchronization with the first clock, with the second clock to generate the second signal and store the second signal in the configuration register in the inside of the interface control device 10. The interface controller of each of the slave devices 43 to 45 may operate according to the second signal of the second domain which is stored in the configuration register.

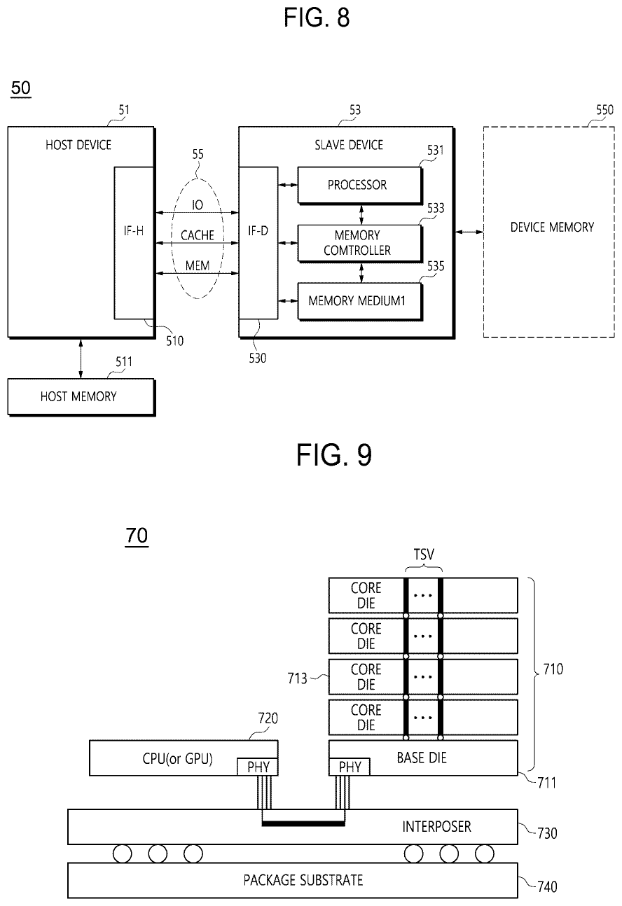

FIG. 8 is a diagram describing an interconnect between data processing systems according to an embodiment of the present disclosure, and illustrates a CXL protocol-based interconnect.

A data processing system 50 may include a host device 51 and a slave device 53. The host device 51 and the slave device 53 may communicate with each other through an interconnect (or a link) 55 which supports at least one protocol. For example, the interconnect may support at least one protocol selected from protocols such as peripheral component interconnect express (PCIe), compute express link (CXL), XBus, NVLink, infinity fabric, cache coherent interconnect for accelerators (CCIX), and coherent accelerator processor interface (CAPI). The interconnect supporting the CXL protocol is illustrated in FIG. 8.

The host device 51 may be coupled to a host memory 511 and may be configured to request data access to the slave device 53.

The slave device 53 may be accessed by the host device 51 and include an interface control device (IF_D) 530, a processor 531, a memory controller 533, and a memory medium 535. A device memory 550 may be connected to the slave device 53.

The host device 51 and the slave device 53 may transmit and receive a message and/or data therebetween through a host interface device (IF-H) 510 and the interface control device 530. For example, the host interface device (IF-H) 510 and the interface control device 530 may relay communication between the host device 51 and the slave device 53.

For example, the host interface device 510 and the interface control device 530 may support a plurality of lower protocols defined in the CXL protocol, and the message and/or data may be transmitted through the plurality of lower protocols. In this example, the lower protocol may include a non-coherent protocol (or I/O protocol; IO) CXL.Io, a coherent protocol (or cache protocol; CACHE) CXL.cache, and a memory access protocol (or a memory protocol; MEM) CXL.mem.

The I/O protocol CXL. io may be an I/O protocol similar to PCIe, and the host device 51 and the slave device 53 included in the data processing system 50 may perform device search, connection, initial setup, virtualization register access, and the like based on the PCIe or I/O protocol CXL.io. In an embodiment, the I/O protocol CXL.io may provide a non-coherent load/store interface.

The cache protocol CXL. cache may be a protocol used so that the slave device 53 accesses the host device 51 to implement cache coherent with the host memory 511. In an embodiment, the cache protocol CXL. cache may include three channels including a request, a respond, and data.

The memory protocol CXL. mem may be a protocol used by the host device 51 to access the memory device 550 of the slave device 53.

In an embodiment, the interface control device 530 may be the interface control device 10 illustrated in FIG. 1. The interface control device 530 may receive the first clock from the host device 51 which operates in the first clock domain and may receive the second clock from the interface controller, which operates in the second clock domain, in the inside of the interface control device 530. The interface control device 530 may synchronize the first signal, for example, the host packet which is transmitted from the host device 51 in synchronization with the first clock, with the second clock to generate the second signal and may store the second signal in the configuration register in the inside of the interface control device 530. The interface controller may operate according to the second signal of the second domain which is stored in the configuration register.

The processor 531 may be an accelerator, which provides functions useful for the host device 51. For example, the processor 531 may include at least one among a programmable component such as a graphic processing unit (GPU), and a neural processing unit (NPU), a component which provides a fixed function such as an intellectual property (IP) core, and a reconfigurable component such as a field programmable gate array (FPGA).

The processor 531 may include a mail box, which is not illustrated in FIG. 8, in the inside or outside thereof. The interface control device 530 may be coupled to the mail box and may transmit and receive the preset type of message to and from the host device 51 through the mail box.

The slave device 53 may include the memory controller 533 configured to access the device memory 550. The memory controller 533 may communicate with the device memory 550 based on a protocol which is dependent on an interconnect 55 or independent of the interconnect 55. The memory controller 533 may access the device memory 550 to read or write data according to control of the processor 531. The memory controller 533 may provide access to the device memory 550 as well as access to the device memory 550 of the host device 51 through the interconnect 55. In some embodiments, the device memory 550 may correspond to a device-attached memory with a CXL specifications.

The slave devices 43 to 45 illustrated in FIG. 7 may be accessed by the host device 51 and the slave device 53 illustrated in FIG. 8 and various types of peripheral apparatuses not illustrated in FIG. 8.

The devices, for example, the slave devices 43 to 45 illustrated in FIG. 7, the slave device 53 illustrated in FIG. 8, and the like, which are accessed by the host devices 41 and 42 illustrated in FIG. 7 or the host device 51 illustrated in FIG. 8 through the CXL interconnect, may be defined as various names, for example, a CXL sub system, a memory system, a in(near)-memory operation unit, and the like.

The CXL protocol is attracting attention to solve the issues for memory shortage and inefficient memory allocation of the host device such as a sever system in a cluster environment.

To overcome a restricted bandwidth of CXL, the host device 51 as the server system may offload the operations with a high memory access to the slave device 53 as the memory adjacent dedicated operation unit such as NDP to perform the operations with the high memory access, and thus an amount of data movement between the host device 51 and the slave device 53 may be reduced.

FIG. 9 is a diagram illustrating a configuration of a data processing system 70 according to an embodiment of the present disclosure.

Referring to FIG. 9, the data processing system 70 may include a stack structure 710 in which a plurality of core dies (CORE DIE) 713 are stacked on a base die (BASE DIE) 711. The stack structure 710 may be configured in a high bandwidth memory (HBM) type in which the plurality of core dies are stacked and electrically coupled through a through silicon via (TSV) to increase the number of I/O units and a bandwidth.

Memory cells configured to store data and circuits for a core operation of the memory cells may be disposed in each of the plurality of dies 713.

The core dies 713 may be electrically coupled to the base die 711 through the through silicon vias TSV and receive a signal and power from the based die 711 through the through silicon vias TSV.

The base die 711 may include, for example, the interface control device 10 illustrated in FIG. 1 or the memory controller 30 illustrated in FIG. 6. The base die 711 may perform various functions within the data processing system 70, for example, a memory management function such as power management and refresh of memory cells or a timing control function between the core die 713 and the base die 711.

A physical region PHY included in the base die 711 may be an I/O region of an address, an instruction, data, a control signal, and the like. The I/O circuits sufficient to satisfy a data processing rate required in the data processing system 70 may be included in the physical region PHY. A plurality of I/O terminals and a plurality of power supply terminals may be included in a physical region PHY portion of a rear surface of the base die 711 to receive the signal and power required in the I/O operation.

The data processing system 70 may include an interface substrate (i.e., interposer) 730.

On the interface substrate 730, the stack structure 710 and the host device 720 such as CPU (or GPU) may be coupled through the physical regions PHY thereof. The interface substrate 730 may refer to an interposer.

The data processing system 70 may be disposed on a package substrate 740. The package substrate 740 and the interface substrate 730 may be electrically coupled to each other through connection terminals.

As the interface control device 10 or 10-1 according to the present disclosure may be adopted to the various memory controllers, data processing systems, and the like, an operation amount for CDC processing, the number of circuits, and the like may be reduced.

The above described embodiments of the present invention are intended to illustrate and not to limit the present invention. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims. Furthermore, the embodiments may be combined to form additional embodiments.

What is claimed is:

1. An interface control device comprising:
a clock domain crossing (CDC) circuit configured to receive, from an external device, a first signal synchronized with a first clock, and output a second signal corresponding to the first signal synchronized with a second clock;
a demultiplexer configured to divide the second signal into a plurality of signals to generate configuration information corresponding to the plurality of signals;
a configuration register configured to store the configuration information; and
an interface controller configured to operate according to the configuration information stored in the configuration register.

2. The interface control device of claim 1, wherein a first number of signals as the first signal are transmitted from the external device, the demultiplexer is configured to divide the first number of second signals output from the CDC circuit into the plurality of signals having a second number larger than the first number.

3. The interface control device of claim 1, wherein the external device is configured to operate in a first clock domain based on the first clock, and the interface controller is configured to operate in a second clock domain based on the second clock.

4. The interface control device of claim 1, wherein the interface control device is configured to communicate with the external device based on at least one of a non-coherent protocol, a coherent protocol, and a memory access protocol.

5. The interface control device of claim 1, wherein the interface control device is configured to communicate with the external device based on a compute express link (CXL) protocol.

6. An operating method of an interface control device, the method comprising:
receiving, from an external device, a first signal synchronized with a first clock;
outputting a second signal corresponding to the first signal synchronized with the second clock received from an internal device;
dividing the second signal into a plurality of signals to generate configuration information corresponding to the plurality of signals;
storing the configuration information; and
performing an interfacing operation based on the configuration information.

7. The method of claim 6,
wherein the first signal has a first number of signals which are transmitted from the external device, and the plurality of signals has a second number larger than the first number.

8. The method of claim 6, wherein the external device is configured to operate in a first clock domain based on the first clock, and the internal device is configured to operate in a second clock domain based on the second clock.

9. The method of claim 6, wherein the interface control device is configured to communicate with the external device based on at least one of a non-coherent protocol, a coherent protocol, and a memory access protocol.

10. The method of claim 6, wherein the interface control device is configured to communicate with the external device according to a compute express link (CXL) protocol.

11. A memory device comprising:
an interface control device;
a device group including at least one memory; and
a device controller configured to control the device group based on signals provided from an external device through the interface control device,
where the interface control device includes:
a clock domain crossing (CDC) circuit configured to receive, from the external device, a first signal synchronized with a first clock, and output a second signal corresponding to the first signal synchronized with a second clock;
a demultiplexer configured to divide the second signal into a plurality of signals to generate configuration information corresponding to the plurality of signals;
a configuration register configured to store the configuration information; and
an interface controller configured to operate according to the configuration information stored in the configuration register.

12. The memory device of claim 11, wherein a first number of signals as the first signal are transmitted from the external device, the demultiplexer is configured to divide the first number of second signals output from the CDC circuit into the plurality of signals having a second number larger than the first number.

13. The memory device of claim 11, wherein the interface control device is configured to communicate with the external device according to a compute express link (CXL) protocol.

14. A data processing system comprising:
at least one first device configured to operate in a first clock domain based on a first clock; and
at least one second device including an interface control device configured to receive, from the at least one first device, a first signal synchronized with the first clock, and operate in a second clock domain based on a second clock,
wherein the interface control device includes:
a clock domain crossing (CDC) circuit configured to receive, from the first device, the first signal synchronized with the first clock, and output a second signal corresponding to the first signal synchronized with the second clock;
a demultiplexer configured to divide the second signal into a plurality of signals to generate configuration information corresponding to the plurality of signals;
a configuration register configured to store the configuration information; and
an interface controller configured to operate according to the configuration information stored in the configuration register.

15. The data processing system of claim 14, wherein the first device and the second device are configured to communicate with each other based on a compute express link (CXL) protocol.

16. The data processing system of claim 14, wherein the second device includes at least one memory device.

17. The data processing system of claim 14, wherein the second device includes a stack structured semiconductor device, and
wherein the stack structured semiconductor device includes:
a package substrate;
an interface substrate stacked on the package substrate;
a controller and a base die stacked on the interface substrate; and
a plurality of core dies stacked on the base die to transmit signals through a plurality of through silicon vias.
